(19) United States
(12) Patent Application Publication
(10) Pub. No.: US 2011/0104509 A1
(43) Pub. Date: May 5, 2011

(54) POLYMER SURFACE MODIFICATION

(75) Inventors: Alexandra H.C. Poulsson, Davos Platz (CH); Robert Geoffrey Richards, Davos Dorf (CH)

(73) Assignee: AO TECHNOLOGY AG, Chur (CH)

(21) Appl. No.: 12/994,337

(22) PCT Filed: May 27, 2009
(86) PCT No.: PCT/EP2009/003744

§ 371 Date: Nov. 23, 2010

(30) Foreign Application Priority Data
May 27, 2008 (EP) 08 156 999.8

(51) Int. Cl. C23C 16/44; C23C 16/505; C23C 16/503; C23C 16/511; C23C 16/56; B32B 27/06

(52) U.S. Cl. 428/524; 427/248.1; 427/2.1; 427/569; 427/575; 427/2.31; 427/2.11; 427/2.24; 427/2.25

(57) ABSTRACT

The present invention relates to a method for increasing hydrophilicity of part or all of a surface of a polymer substrate to change the ability of a polymer surface to bond, allowing better adhesion or printability, by a surface treatment which increases the surface energy stabilised by several washing steps.

### FIELD OF THE INVENTION

The present invention relates to a method for increasing hydro- philicity of part or all of a surface of a polymer substrate to change the ability of a polymer surface to bond, allowing better adhesion or printability, by a surface treatment which increases the surface energy stabilised by several washing steps.

### BACKGROUND

It may be considered advantageous to change the nature of polymer surfaces, such as polymer surfaces for medical devices, automotive, aeronautical, marine or electrical applications to improve the bonding properties of polymer surfaces in order to widen their applications. A change in the surface of the polymer can affect the manner in which chemical species, biological tissues, cells (such as functional groups/ions, proteins, water, etc) react, adsorb, wet, bond or interact with the material surface. A change in surface nature may be performed by a variety of ways comprising, but not limited to, alteration of the surface chemistry (such as alteration of surface molecular weight, addition or alteration of functional chemical groups, incorporation of radicals, chemical species, polarity of the surface, etc), surface energy, surface topography (such as surface roughness, micro- or nano-scale patterned or random surface patterns), surface crystallinity, surface mechanical properties (such as mechanical stiffness, hardness or yield strength), incorporation of micro- or nano-scale materials in the surface layer/layers (such as micro- or nano-particulates or -fibres) or a combination thereof.

The incorporation of chemical species in or onto the material surface can alter the wettability of the surface. This altered wettability may effect the bonding strength between the surface polymer and material bonded onto it, when this is achieved by adsorption, printing, painting, welding/melt-bonding, gluing and other processes of material bonding known to those skilled in the art. Examples of adsorption include the bonding of proteins and cells (cellular adhesion and spreading, viability where an up-regulation of extra cellular matrix production and other changes in functionality could occur) onto a medical device implanted into the human body. A reduction in bacterial adhesion may also be observed as a result of an altered protein adhesion due to an increase in surface energy. The surface chemistry of the implant and thereby surface energy affects the way in which proteins adsorb and conform on the surface which directs cellular adhesion. Examples of printing include bonding of inks onto polymer surfaces for consumer product packaging, or the printing of electronic circuits onto PCBs (printed circuit boards). Examples of painting include the application of functional and aesthetic coatings to protect, seal, decorate polymer surfaces, for example painting of decorative colours onto plastic car bumpers. Examples of welding/melt-bonding include over-moulding of one polymer in a melt form onto another polymer in a solid form in an injection moulding process, or bonding of polymer fibres to a polymer matrix in composite manufacture. Examples of gluing include the use of an adhesive medium to bond two surfaces together such as the bonding of labels to polymeric products.

There are numerous applications in which it would be advantageous to improve the ability of polymers to bond to another material or themselves. The ability of polymers to bond to other materials is controlled by a variety of factors including surface chemistry, topography (on the nano-, micro- and macro-scale) and wettability of both surfaces to be bonded. This also applies when both materials are polymeric, or one material is a polymer and the other can be metal, ceramic, composite, paint, adhesive, biological material, glass or rubbers in a solid, particulate, fibrous, textile, gel, slurry or liquid form or a combination thereof.

There are numerous polymers used in a variety of applications where improved adhesion is desired, ranging from electrical devices including semiconductors to medical applications. Polyethers, in particular polyarylethers (such as e.g. polyetheretherketone (PEEK) known for its high strength, good wear resistance and radiolucent properties), are currently of great interest to replace metals in applications such as spine cages and craniomaxillofacial (CMF) implants. X-ray evaluation of soft and hard tissue integration to implants can be obscured by the presence of the metal devices, such as for example Titanium devices. In addition, MRI examination of Titanium implants can lead to so called “black hole artefacts” where the implant appears larger than in reality, making visualisation of post-operative recovery problematic, and preventing visualisation adjacent to the implant. Owing to the problem of visualisation the devices have been redesigned in a polymeric materials. It would therefore be advantageous to use implants in a radiolucent material such as PEEK. However, while PEEK has a combination of good strength, wear properties and chemical resistance, it suffers from low surface energy, an intrinsic problem for most polymers. Surfaces with higher energy have been shown to have improved bonding abilities including the promotion of rapid cellular adhesion and spreading, whereas low energy surfaces do not. At the same time, surface topography has also been found to influence cell-surface bond strength and thereby also influence cell orientation and attachment.

One major drawback of surface treatments which are currently available for polymer substrates is that the effect gained by the surface treatment is unstable, and so is rapidly lost over time, leading to a short shelf-life of the treated surface and storage instability. Lack of stability of the treated surface poses a tremendous problem in particular for polymers used for (in vivo) medical applications as it may result in undesired features such as alteration of the substrate properties and/or an altered degradation profile and thus possible unpredictable results and/or undesired side effects.

Applicants have now found a method for increasing the surface energy of a polymer substrate using plasma surface treatments (e.g. oxidative treatments) to obtain a surface which can promote bond strength between materials (thereby reducing failure rates between materials), e.g. promotion of cellular adhesion, spreading, viability, and functionality (thereby reducing undesirable biological responses and improving the cell-biomaterial interface). Moreover, the effects of the surface treatment of the invention can be retained over long time periods, such as several months.

### SUMMARY OF THE INVENTION

In a first aspect the present invention provides a method for increasing hydrophilicity of part or all of a surface of a polymer substrate comprising the steps of (a) exposing the surface to a plasma treatment, comprising but not limited to oxidative treatments with a suitable gas, preferably oxygen, and (b) subjecting it to one or more washing steps to stabilise the surface by removing any loosely bound low molecular weight oxidized material and allowing unsaturated bonds to react and radicals and excited species to be quenched.

The polymer substrate may be for use in any application, where improved bonding ability is desirable, including, but not limited to, medical applications.

In another aspect the present invention provides a method for increasing adhesion, e.g. cellular adhesion, to part or all of a surface of a polymer substrate, e.g. a polymer substrate for use in a medical article, comprising the steps of (a) exposing the surface to a plasma treatment, comprising but not limited to an oxidative treatment with a suitable gas, preferably oxygen, and (b) subjecting it to one or more washing steps to remove any low molecular weight oxidised material produced by the surface treatment.

It is another aspect underlying the present invention to provide a surface modification of a polymer substrate for use in e.g. medical applications that shows long-term stability.

According to one embodiment of the present invention the oxidative treatment is an atmospheric or vacuum ionizing plasma treatment.

According to another embodiment of the present invention the plasma is generated by a power source selected from the group consisting of an alternating current (AC), a direct current (DC) low frequency (LF), audio frequency (AF), radio frequency (RF) and microwave power source, preferably a microwave or an RF power source

According to another embodiment of the present invention the polymer substrate is selected from the group consisting of polyolefins, polyethers, polyamides, polyimides, polyetherimides, halogenated polymers, polycarbonates, polyurethanes, polysulfones, aromatic polymers, polyesters, polyacrylates, polyols, liquid crystal polymers or copolymers, blends or mixtures thereof, preferably polyolefins and polyethers.

According to another embodiment of the present invention the polymer substrate is in form of a block, sheet, film, strand, fibre, piece or particle, powder, shaped article, woven fabric or massed fibre pressed into a sheet

According to another embodiment of the present invention the polymer substrate represents all or part of a device, a cell or tissue culture scaffold, a kit, an analytical plate, an assay or the like.

In another aspect the present invention provides a surface treated polymer substrate for use in medical applications obtained by a method according to the invention.

### BRIEF DESCRIPTION OF THE FIGURES

FIG. 1: Surface oxygen concentration of washed and unwashed oxygen plasma treated PEEK surfaces.

FIG. 2. Stability of plasma surface treatment after 8 months as determined by XPS.

FIG. 3: SEM of human primary osteoblast-like cell (HOB) attachment after 2 days of culture on untreated PEEK (A) showing the poor adhesion of the HOB cells and HOB cells on treated PEEK to have a more attached, flattended appearance(B).

FIG. 4: Mineralization of human primary osteoblast-like cells, as determined by ARS staining on surface treated PEEK surfaces compared to untreated PEEK, titanium and Thermanox.

### DETAILED DESCRIPTION

In a first aspect the present invention provides a method for increasing hydrophilicity of part or all of a surface of a polymer substrate comprising the steps of (a) exposing the surface to a plasma treatment, comprising but not limited to oxidative treatments with a suitable gas, preferably oxygen, and (b) subjecting it to one or more washing steps.

In another aspect the present invention provides a method for increasing adhesion to part or all of a surface of a polymer substrate, comprising the steps of (a) exposing the surface to a plasma treatment, comprising but not limited to an oxidative treatment with a suitable gas, preferably oxygen, and (b) subjecting it to one or more washing steps.

In specific embodiments the one or more washing steps include immersion of the surface obtained in step (a) in a washing medium, followed by removal of the washing medium from the surface. The washing step may then be repeated with fresh washing medium, for the same or a longer period of time as the preceding immersion.

The washing steps may be performed using a rotating platform, whereby a surface immersed in a washing medium is placed on a rotating platform. In one embodiment 1 to 10 washing steps are performed, preferably 2 to 5.

Examples of the washing medium used for such a purpose include:

Aqueous solvents, such as water and alcohols, e.g. lower alcohols such as methanol, ethanol, propanol, isopropanol and t-butanol; aliphatic hydrocarbon solvents such as n-pentane, isopentane, n-hexane, isohexane, n-heptane, 2,2,2-trimethylpentane, n-octane, isooctane, cyclohexane and methylcyclohexane; aromatic hydrocarbon solvents such as benzene, toluene, xylene, ethylbenzene, trimethylbenzene, methylethylbenzene, n-propylbenzene, isopropylbenzene, diethylbenzene, isobutylbenzene, triethylbenzene, diisopropylbenzene and n-amylnaphthalene; and ketone solvents such as acetone, methyl ethyl ketone, methyl n-propyl ketone, methyl n-butyl ketone, methyl isobutyl ketone, cyclohexanone, 2-hexanone, methylcyclohexanone, 2,4-pentanedione, acetonylacetone, diacetone alcohol, and acetophenone.

Preferred washing mediums include in particular aqueous solvents, aliphatic hydrocarbon solvents and ketone solvents, such as (distilled) water, methanol, ethanol, isopropylalcohol, acetone, soap solutions, toluene, perchloromethane or isopentane, more preferably aqueous solvents such as water, methanol and ethanol.

These solvents may be used either singly or in combination.

It has been shown that the washing steps allow the surface to stabilise by e.g. removing any loosely bound low molecular weight oxidized material (such as produced by the surface treatment) and/or allowing unsaturated bonds to react and/or allowing radicals and excited species to be quenched.

The method of the present invention may be applied to surfaces of numerous polymer substrates used in various applications where improved adhesion and/or attachment are desirable. These include e.g. medical applications, automotive, aeronautical, marine or electrical applications, in particular medical applications where improved cell adhesion and attachment are of importance.

As used herein, the term “polymer” or (“polymer substrate”) may include, but is not limited to, polyolefins such as low density polyethylene (LDPE), polypropylene (PP), high density polyethylene (HDPE), ultra high molecular weight polyethylene (UHMWPE), blends of polyolefins with other polymers or rubbers; polyethers (including polyarylethers) such as polyetheretherketone (PEEK), polyetherketoneketone (PEKK), and polyaryletherketoneetherketoneketone (PEKEKK); polyamides, such as poly(hexamethylene adipamide) (Nylon 66); polyimides; polyetherimides; polycarbonates; polyurethanes; polysulfones; halogenated polymers, such as polyvinylidenefluoride (PVDF), polytetrafluoroethylene (PTFE) (Teflon™), fluorinated ethylene-propylene copolymer (FEP), and polyvinyl chloride (PVC); aromatic polymers, such as polystyrene (PS); polyacrylates such as polymethylmethacrylate; polyols such as polyvinyl alcohol; polyesters, such as polyethylene terephthalate (PET), polyethylene naphthalate (PEN), polylactic acid, polyglycolic acid; and copolymers, such as ABS and ethylene propylene diene mixture (EPDM). Thus, the polymer substrate may be a homopolymer, copolymer, one or more polymer containing materials, a mixture or blend or polymer matrix composite.

In a further embodiment the polymer substrate is biocompatible.

Preferred polymers include polyolefins such as polyethylene and polyethers, e.g. polyarylethers, more preferably PEEK.

The term “surface” as defined herein is defined as the outer 5 mm, preferably the outer 1 mm of a material.

The term “plasma” as used herein describes the state of partially or completely ionised gas. A plasma consists of charged ions (positive or negative), negatively charged electrons, and neutral species, radicals and excited species. The term “plasma treatment” as used herein means a treatment of exposing the surface of a substrate to an environment under plasma state, thereby subjecting the surface to the chemical, physical and mechanical (bombardment) actions of the plasma. As known in the art, a plasma may be generated for example by a power source such as an alternating current (AC), a direct current (DC) low frequency (LF), audio frequency (AF), radio frequency (RF) and microwave power source, preferably a microwave or an RF power source.

In radiofrequency (RF) discharge, a substrate to be treated is typically placed in a vacuum chamber and gas at low pressure is bled into the system until the desired gas pressure in the chamber and differential across the chamber is obtained. An RF electromagnetic field is generated within the apparatus by applying current of the desired frequency to the electrodes from an RF generator. The partial or complete ionisation of the gas in the apparatus is induced by the electromagnetic field, and the resulting plasma in the chamber modifies the polymer substrate surface subjected to the treatment process.

The plasma forming gas may be selected from the group consisting of oxygen, hydrogen, nitrogen, air, helium, neon, argon, carbon dioxide and carbon monoxide, methane, ethane, propane, tetrafluoromethane, and hexafluoroethane or a combination of the aforementioned gases. The preferred plasma forming gas used to treat the surface of the polymer substrate according to the invention is oxygen, either singly or as a mixture (e.g. with one or more further plasma forming gases).

Typical plasma treatment conditions as used herein may include power levels from about 1 watt to about 1000 watts, preferably between about 5 watts to about 500 watts, most preferably between about 10 watts to about 100 watts (an example of a suitable power is forward power of 100 watts and reverse power of 12 watts).

Preferred frequencies are of about 1 kHz to 100 MHz, preferably about 15 kHz to about 50 MHz, more preferably from about 1 MHz to about 20 MHz, most preferably about 13.5 MHz.

Preferred axial magnetic field strengths are of between about 0 G to about 100 G, preferably between about 20 G to about 80 G, most preferably between about 40 G to about 60 G.

Preferred exposure times are of about 5 seconds to 12 hours, preferably about 1 minute to 2 hours, more preferably between about 5 minutes and about 30 minutes.

Preferred gas pressures are of about 0.0001 to about 10 torr, preferably between about 0.0005 torr to about 1.0 torr, most preferably between about 0.1 torr and about 0.5 torr.

Typical gas flow rates are of about 1 to about 2000 cm³/min, preferably between 150-300 cm³/min. Preferably the treatment takes place at a temperature of from 0° to 30° C.

Following plasma treatment the polymer substrate surface is subjected to one or more washing steps as described hereinbefore, e.g. to stabilise the surface and to remove any low molecular weight oxidized material, using a suitable washing medium, preferably water, methanol, ethanol, isopropylalcohol, acetone, soap solutions, toluene, perchloromethane or isopentane, more preferably an aqueous solution such as distilled water.

In a final step the so obtained surface treated polymer substrate is subjected to thorough drying, e.g. using nitrogen flow or in a so called clean air environment such as a laminar flow hood.

Optionally the surface treated polymer is subjected in a further step to sterilisation by steam-autoclave, hydrogen-peroxide gas sterilisation or gamma sterilisation.

The applicants have shown that the surface treated polymer substrate according to the invention show an outstanding improved (long-term) stability and increased shelf life. The term “(storage) stability” or “shelf life” as used herein means stable at those temperatures and conditions potentially encountered in storage, transport and use for a period of at least about four months, preferably at least about eight months, more preferably at least about one year or more.

Thus, the surface treated polymer substrate may be used immediately or stored (for example in a sealed environment) for a period of minutes up to several months before its intended use.

In a further aspect the present invention provides a surface treated polymer substrate for use in medical applications obtained by a method according to the invention.

In one embodiment the polymer substrate may be in form of a block, sheet, film, strand, fibre, piece or particle, powder, shaped article, woven fabric or massed fibre pressed into a sheet.

In another embodiment the polymer substrate represents all or part of a medical device (e.g. a stent, a prosthesis, an artificial joint, a bone or tissue replacement material, an artificial organ or artificial skin, an adhesive, a tissue sealant, a suture, a membrane, staple, nail, screw, bolt, spine cage or other device for surgical use, or other implantable device) a cell or tissue culture scaffold, a kit, an analytical plate, an assay or the like.

The invention is described further by way of the following non-limiting examples.

### EXAMPLES

Materials and Methods: PEEK Optima™ discs (Invibio Ltd) were machined to 13 mm diameter and were modified by RF plasma treatment. Thermanox (Nunc) and Ti ISO 5832/2 (Synthes) were used as the control surfaces. Oxygen plasma treatment was performed using an EMITECH RF plasma treater at 13.56 MHz, 0.1-0.5 Torr for up to 30 min. Surface chemical compositions of treated and untreated surfaces were characterised by XPS and contact angle; topographic changes by AFM. Primary human osteoblasts-like cells (HOB, Promocell) or those isolated from femoral heads removed during total hip replacement operations were grown to 70-80% confluence in DMEM (10% FCS in 5% CO² at 37° C.), and plated at 10000 cells/cm². Alpha-MEM (0.11 μm dexamethasone and 10 mM betaglycerophosphate) was used as mineralisation media over 21 days. Cell functionality was assessed by alkaline phosphatase activity (ALP), phenotypic gene expression by qPCR, mineralisation by Alizarin red S (ARS) staining of calcium deposits, total protein, cell attachment by SEM and cell density through the alamarBlue™ assay. Sampling was performed at 1, 7, 14, 21 and 28 days.

### Example 1

### Surface Treatment of PEEK

If necessary, the PEEK sample was first subjected to a cleaning process such as sonication in isopropanol alcohol, ethanol or methanol, optionally followed by cleaning in distilled water.

Subsequently, the PEEK sample was then placed inside a commercial plasma treater, with an oxygen-rich gas atmosphere. The pressure in the chamber was reduced to a partial vacuum between 3−7×10⁻¹ mbar, and a low pressure plasma was created. The PEEK sample was exposed to the plasma for 10 min. Once the chamber has been brought back to atmospheric pressure, the samples were removed, and placed in distilled water which was repeatedly replaced with fresh distilled water in the subsequent hour. To aid in removal and to stabilise the surface the samples were placed on a rotating platform while immersed in the washing medium to allow thorough removal of any low molecular weight oxidized material which had been created during the exposure to the oxygen plasma. After the 3^{rd} wash with distilled water the samples were removed and placed within a sterile tissue culture dish within a class II laminar flow hood to dry overnight. Samples were then sterilised by steam-autoclave to confirm surface stability by surface analytical techniques or plated with HOB cells.

### Example 2

### Analysis of Surface Oxygen

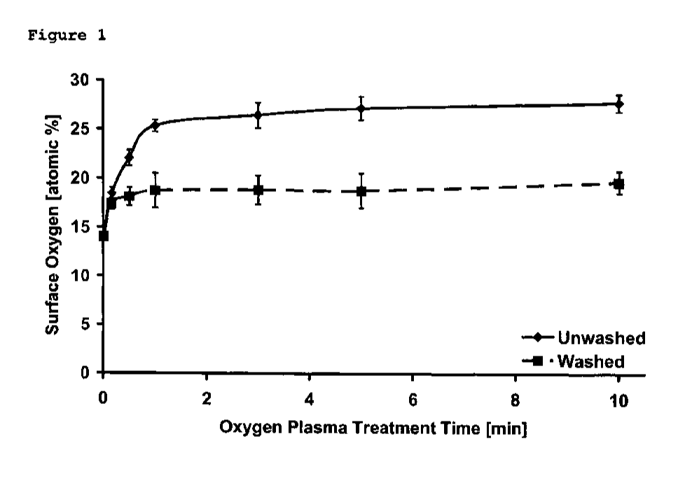

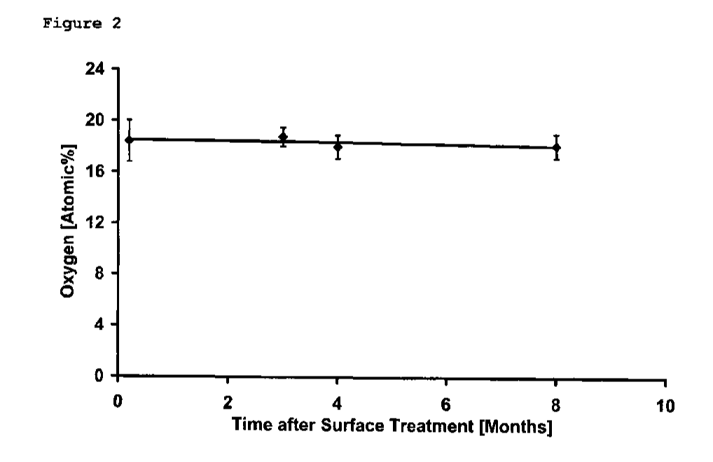

Untreated PEEK samples, treated and unwashed PEEK samples, and treated and washed PEEK samples were compared to determine the effect of the surface treatment and washing on the PEEK samples. X-ray photoelectron spectroscopy (XPS) analysis of untreated PEEK showed 12-14 atomic % surface oxygen, indicating that these surfaces are relatively hydrophobic in character. XPS analysis of the unwashed, treated PEEK surfaces showed that the surface oxygen concentration increased with increasing treatment time up to 27.5 atomic %. The treated and washed PEEK surfaces showed the surface oxygen concentrations increased with increasing treatment time up to 20 atomic %. Following the washing procedure the surface oxygen concentrations decreased as a result of the removal of low molecular weight oxidised material (see FIG. 1). High resolution C1s spectra showed an increase in C—O type functional groups, with a lesser increase in C═O and O—C═O functional groups. XPS and contact angle measurements showed that the surface modification of the washed surfaces was stable for more than 8 months (see FIG. 2) while on the unwashed surfaces a decrease in surface oxygen and an increase in contact angle after surface treatment was observed.

### Example 3

### Analysis of Surface Cell Attachment

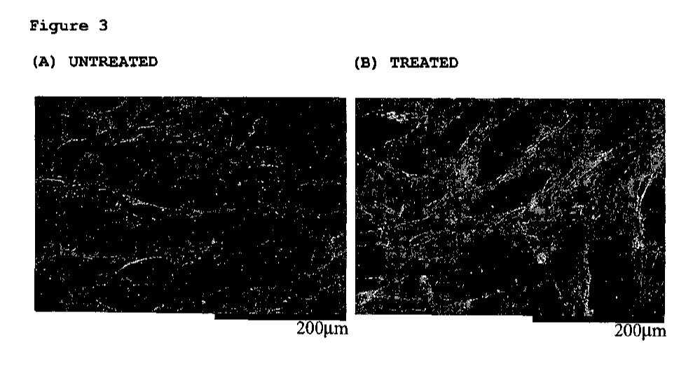

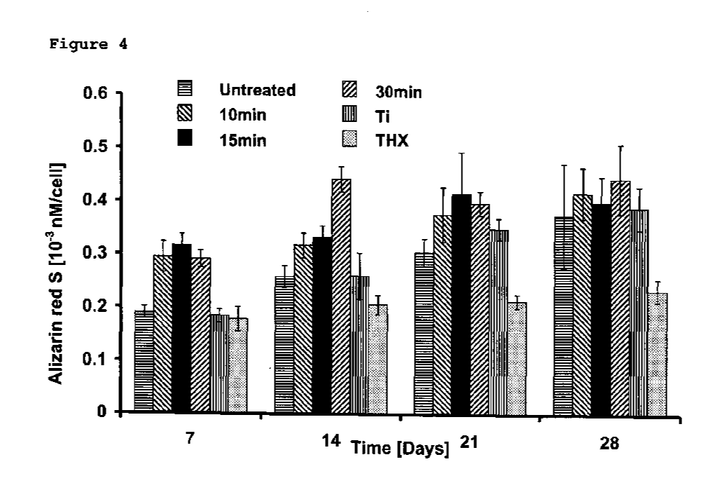

To study the effects of the surface treatment on human primary osteoblast-like (HOB) cell attachment and functionality, the cells were observed after plating on the treated and untreated PEEK, titanium discs (Synthes, CH) and tissue culture PS (Nunc, DK). Within 24 hrs, the treated surfaces were shown to have higher cell densities than the untreated surfaces. By day 21 the treated surfaces were shown to have similar cell densities to titanium. Scanning electron micrographs of the HOB cell attachment after 2 days of culture on untreated PEEK (FIG. 3A) shows the cells to be poorly adhered while the HOB cells on treated PEEK (FIG. 3B) have a more attached, flattended appearance. Cell attachment was also shown to be improved on the treated surfaces compared to untreated PEEK surfaces, which led to an up-regulation in differentiation, where mineralization markers were identified at earlier timepoints. Mineralization of the HOB cells (see FIG. 4), as determined by ARS staining on surface treated PEEK surfaces compared to untreated PEEK, standard titanium and tissue cell culture polystyrene (Thermanox, Nunc, DK), showed that the HOB cells produced a mineralized extra cellular matrix at earlier time-points on the treated PEEK surfaces than the untreated PEEK surfaces.

1. A method for increasing hydrophilicity of part or all of a surface of a polymer substrate, comprising the steps of (a) exposing the surface to a plasma surface treatment with a suitable gas, preferably an oxidative treatment with oxygen, and (b) subjecting it to one or more washing steps to remove any low molecular weight oxidized material.

2. A method according to claim 1, wherein the polymer substrate is a polymer substrate for use in medical applications.

3. A method for increasing adhesion to part or all of a surface of a polymer substrate, comprising the steps of (a) exposing the surface to a plasma surface treatment with a suitable gas, preferably an oxidative treatment with oxygen, and (b) subjecting it to one or more washing steps to remove any low molecular weight oxidized material.

4. A method for increasing cellular attachment to part or all of a surface of a polymer substrate for use in a medical article, comprising the steps of (a) exposing the surface to a plasma surface treatment with a suitable gas, preferably an oxidative treatment with oxygen, and (b) subjecting it to one or more washing steps to remove any low molecular weight oxidized material.

5. A method according to claims 1, 3 or 4, wherein the oxidative treatment is an atmospheric or vacuum ionizing plasma treatment.

6. A method according claim 5, wherein the plasma is generated by a power source selected from the group consisting of an alternating current (AC), a direct current (DC) low frequency (LF), audio frequency (AF), radio frequency (RF) and microwave power source, preferably a microwave or an RF power source.

7. A method according to claim 5, wherein said oxidative treatment takes place at a temperature of from 0° to 25° C.

8. A method according to claim 5, wherein said oxidative treatment takes place at a pressure of from 0.1 to 0.5 torr.

9. A method according to claim 1, 3, or 4, wherein the polymer substrate is selected from the group consisting of polyolefins, polyethers, polyamides, polyimides, polyetherimides, halogenated polymers, polycarbonates, polyurethanes, polysulfones, aromatic polymers, polyesters, polyacrylates, polyols, liquid crystal polymers or copolymers, blends or mixtures thereof.

10. A method according to claim 1, 3, or 4, wherein the polymer substrate is a homopolymer, copolymer, one or more polymer containing materials, a mixture or blend or polymer matrix composite.

11. A method according to claim 1, 3, or 4, wherein the polymer substrate is biocompatible

12. A method according to claim 1, 3, or 4, wherein the polymer substrate is in form of a block, sheet, film, strand, fibre, piece or particle, powder, shaped article, woven fabric or massed fibre pressed into a sheet.

13. A method according to claim 1, 3, or 4, wherein the polymer substrate represents all or part of a medical device, a cell or tissue culture scaffold, a kit, an analytical plate, an assay or the like.

14. A method according to claim 13, wherein the medical device is selected from a stent, a prosthesis, an artificial joint, a bone or tissue replacement material, an artificial organ or artificial skin, an adhesive, a tissue sealant, a suture, a membrane, staple, nail, screw, bolt, spine cage or other device for surgical use, or other implantable device.

15. Surface treated polymer substrate for use in medical applications obtained by a method according to claim 1, 3, or 4.
